(19) United States
(12) Patent Application Publication
(10) Pub. No.: US 2021/0273247 A1
(43) Pub. Date: Sep. 2, 2021

(54) METHOD AND SYSTEM FOR IDENTIFYING A LEAK WITHIN A MEMBRANE OF A FUEL CELL

(71) Applicant: Robert Bosch GmbH, Stuttgart (DE)

(72) Inventors: Helerson Kemmer, Vaihingen (DE); Shinichi Makino, Kanagawa-ken (JP)

(21) Appl. No.: 17/254,440

(22) PCT Filed: Jun. 17, 2019
(86) PCT No.: PCT/EP2019/065834

§ 371 Date: Dec. 21, 2020

(30) Foreign Application Priority Data
Jun. 20, 2018 (DE) 10 2018 209 932.4

(51) Int. Cl. H01M 8/04664; H01M 8/04537; H01M 8/04828; G01R 31/392; B60L 58/30

(52) U.S. Cl. CPC H01M 8/04679; H01M 8/04552; H01M 2250/20; G01R 31/392; B60L 58/30; H01M 8/0494

(57) ABSTRACT

A method for identifying a leak (4′) within a membrane (4) of a fuel cell (5) during operation of a motor vehicle, comprising the steps: reducing the power provided by the fuel cell (5) starting from an output power to a minimum value; determining measurement values of the current cell voltage of the fuel cell (5) whilst the reduced power at the minimum value is provided by the fuel cell (5); and assessing a state of the membrane (4) of the fuel cell (5) on the basis of the determined measurement values in order to identify a leak (4′). The power reduced by the fuel cell (5) whilst measurement values of the current cell voltage are determined is provided at the same level by at least one further energy source.

### BACKGROUND OF THE INVENTION

The present invention is based on a method according to the generic type of the independent method claim and also based on a system according to a generic type of the independent system claim.

Frequent sources of defects in fuel cells relate to leaks within the membranes that are used for separating the reaction gases. Since it is not possible to prevent such leaks occurring either within the respective production processes or by means of using subsequent test procedures, methods and systems for detecting such leaks are indispensable. In particular when using PEM fuel cells, it is necessary for safety-relevant reasons to detect larger leaks in order to switch off the relevant systems as quickly as possible if leaks of this type occur—and thus to be able to avoid possible explosions caused as a result of oxyhydrogen reactions. In order to detect leaks within the membrane of fuel cells, the prior art discloses, in addition to the detection method which uses a hydrogen sensor in the exhaust gas, above all the detection method which monitors the cell voltage (CVM=cell voltage monitoring). The latter mentioned method is based in this case on the detection of an interruption in the cell voltage which is caused by means of a direct transport of hydrogen through the leak within the membrane. In this case, the cell voltage is interrupted as a result of the fact that the hydrogen portion that is transported directly through the membrane is not oxidized at the anode to form protons and consequently does not contribute to the increase in the cell potential.

### SUMMARY OF THE INVENTION

The subject matter of the invention is a method having the features of the independent method claim and also a system having the features of the independent system claim. In this case, features and details that are described in conjunction with the method in accordance with the invention naturally also apply in conjunction with the system in accordance with the invention and conversely in each case with the result with regard to the disclosure reference always conversely refers to or can refer to the individual aspects of the invention.

The method in accordance with the invention is used in particular to detect a leak within the membrane of a fuel cell during the operation of a motor vehicle. In this case, the advantage of the method is above all to be seen in the fact that a particularly meaningful measuring method is disclosed that can be performed under full-load conditions. A meaningful detection of leaks under full-load conditions is in this case in particular problematic since the cell voltage of a fuel cell drops owing to activation losses and ohmic losses as the cell load increases and the method for detecting a leak by means of monitoring the cell voltage is based in particular on the detection of an interruption in the cell voltage with the result that the voltage differences that are necessary for detection purposes can no longer be registered as the cell load increases. Consequently, a meaningful measurement can only be performed by means of the said methods in the current manner in a state in which the relevant cell is hardly loaded or is not loaded at all and consequently hardly any or no current is provided by or tapped from the fuel cell. However, this is particularly disadvantageous in the case of fuel cells being used in mobile systems in which it is necessary to ensure the permanent supply of energy to the systems.

The method in accordance with the invention for detecting a leak within a membrane of a fuel cell can be used in this case in particular in a fuel cell vehicle, such as for example a motor vehicle, a crane or a fork lift truck. In this case, a leak is to be understood within the scope of the invention to be a cut-out, in particular an opening or a hole, through which solids, liquids or gases can enter or discharge. In the case of the method in accordance with the invention, a power that is provided by means of the fuel cell is in this case initially reduced starting from an output power to a minimal value. In the ideal case, the minimal value of the power that is provided by the fuel cell amounts to a value of 0 Watt, in other words the value that can be measured if the fuel cell is not providing any power. However, it is likewise possible that the minimal value is higher, for example multiple kilowatt or the like. In this case, it is possible for the power to reduce to the minimal value in steps or also continuously.

After a reduction of the power that is provided by means of the fuel cell to a minimal value, measurement values of the prevailing cell voltage of the fuel cell are determined in accordance with the invention while the power that has reduced to the minimal value is provided by the fuel cell. The procedure of determining the measurement values can be performed in this case directly or indirectly. In the case of a direct measurement procedure, it is possible for example to measure directly a value that is relevant for detecting a leak within a membrane of a fuel cell, whereas, in the case of an indirect measurement procedure, a value that has already been measured is merely received. The measurement values are in particular measurement values of the prevailing cell voltage of the fuel cell.

After measurement values of the prevailing cell voltage of the fuel cell have been determined, a state of the membrane of the fuel cell is assessed within the scope of the method in accordance with the invention with the aid of the determined measurement values for detecting a leak. In this case, it is possible to select preferably freely and in a variable manner both the time interval for determining the measurement values and also the rate of the measurement value determination procedure until an assessment procedure is performed with the aid of the measurement values. In order to realize a particularly meaningful assessment of a state of the membrane of the fuel cell, the assessment procedure is advantageously performed only after a specific number of measurement values have been determined, in particular after averaging and/or weighting the measurement values. The state that is assessed within the scope of the method in accordance with the invention relates in this case in particular to a prevailing magnitude of the leak within the membrane of a fuel cell.

In accordance with the characterizing feature of the method that is the subject matter of the invention, the reduced power from the fuel cell during the procedure of determining the measurement values of the prevailing cell voltage is compensated for in an equal amount by means of at least one further energy source. The at least one further energy source is preferably an electrical, in particular an electrochemical, energy source. In this case, the energy source can be a current source or voltage source for example a battery, a capacitor, a super capacitor or the like. Likewise, the reduced power from the fuel cell can also be compensated for by more than one, for example by two or three, energy sources. Within the scope of the method in accordance with the invention, it is recognized that by virtue of compensating for the power reduced during the procedure of determining the measurement values, it is possible to perform a sensitive detection method even during the full operation.

In order to be able to ensure within the scope of a reliable method that, preferably during the entire performance of the method in accordance with the invention, the reduced power from the fuel cell can also be compensated for by the at least one further energy source, it can be provided advantageously in accordance with the invention that prior to the reduction of the provided power a test is performed with respect to the prevailing feasibility of the method. In this case, a test of this type can include in particular a test of the prevailing charge state of the at least one further energy source. Furthermore, the test can preferably include a comparison of the currently available charge capacity with a predicted energy consumption during the performance of the method in accordance with the invention. The predicted energy consumption can be based in this case for example on the determinable temporal duration of the performance of the method, during which the at least one other energy source compensates for the reduced energy supply from the fuel cell. In addition, it is also possible to include further data into the estimation of a predicted energy consumption, such as a prevailing route profile, prevailing weather conditions, the prevailing traffic situation and use of specific preferences, such as a possible rapid transportation or the like.

A particularly simple test with respect to the prevailing charge capacity of the at least one other energy source can be performed for example also indirectly with the aid of the most recent periods of use of the at least one other energy source. The testing procedure can thus include for example a comparison of the duration of the operation of the fuel cell under full load with a comparison value. It is hereby possible in a particularly simple manner to ensure that the at least one further energy source has not made available a charge capacity during the duration of the operation of the fuel cell under full load and that its charge capacity does not reduce during this time but rather at the most has further increased by means of the recuperation processes or the like.

Within the scope of a cost-effective and simultaneously safe performance of the method in accordance with the invention, it is possible to provide with regard to the subject matter of the invention that the power that is provided by means of the fuel cell reduces during the method and is increased back to the same extent after the measurement values of the prevailing cell voltage have been determined, in particular after and in dependence upon the performed assessment procedure, wherein the reduced power from the fuel cell is compensated for by means of the at least one further energy source and this power that is provided by the at least one further energy source is reduced accordingly by the same amount after the power that is provided by the fuel cell increases. In order in the event of a leak being detected not to resume operation of the fuel cell until the problem has been eliminated and/or to initiate further safety-relevant steps, such as for example interrupting the gas supply or the like, it is particularly expedient in this case to compensate for the reduced power from the fuel cell by means of the at least one other energy source until an assessment procedure has been performed. In contrast, within the scope of a particularly cost-effective performance of the method in accordance with the invention, it is also expedient to provide the power that has reduced during the method immediately after determining the measurement values of the prevailing cell voltage by means of the fuel cell and not to continue to provide the power by means of the least one further energy source. In the latter case, the at least one further energy source must only compensate for the reduced power from the fuel cell for a shorter period of time with the result that the energy source can be embodied so as to be smaller. When using the method in accordance with the invention in a vehicle, this means that the weight is reduced and accordingly also the consumption of the vehicle is reduced.

Since—as mentioned above—the cell voltage of a fuel cell drops owing to activation losses and ohmic losses as the cell load increases and these processes lead to the fact that the voltage differences between a state with a leak and a state without a leak become smaller as the cell load increases, these voltage differences being necessary for detecting a leak with in a membrane of a fuel cell, it is possible within the scope of a sensitive as possible measurement method to provide in accordance with the invention advantageously that the power that is provided by means of the fuel cell is reduced prior to and/or during the procedure of determining measurement values of the prevailing cell voltage and in particular during and in dependence upon the performed assessment procedure to a value of less than 2% of the maximal power, preferably to a value of less than 1% of the maximal power, in particular to a value of less than 0.1% of the maximal power. Depending upon the power of the relevant fuel cell system, it is consequently possible to reduce the power provided by means of the fuel cell for example to a value of less than 2 kW, preferably to a value of less than 1 kW, in particular to values of less than 0.1 kW. The best possible measurement conditions with respect to sensitivity, in other words the conditions in which with the aid of the method in accordance with the invention it is possible to perform the detection procedure in the most sensitive manner, prevail if power is not being provided or if the highest cell voltage is applied. Accordingly, it is possible with respect to a particularly sensitive performance of the method that is the subject matter of the invention to also provide that the method is performed at least in part in the case of an open circuit voltage of the fuel cell. In particular, it can be expedient within the scope of a particularly meaningful performance of the method that is the subject matter of the invention to determine measurement values of the cell voltage in the case of differing power values of the fuel cell and to extrapolate these measurement values with the aid of ideal curve progressions. Consequently, it is currently not necessary to reduce the power that is provided by the fuel cell until the open circuit voltage is achieved. As an alternative, measurement values of the cell voltage in the case of differing power values of the fuel cell can be determined and can be extrapolated with the aid of these values to the cell voltage in the case of an open circuit voltage. The value of the cell voltage determined in this manner in the case of an open circuit voltage can then be assessed within the scope of the assessment procedure in accordance with the invention with respect to the presence of a leak within the membrane of the relevant fuel cell.

Within the scope of the particularly meaningful measurement or assessment procedure, it can be particularly expedient in this case to reduce in steps the power that is provided by means of the fuel cell prior to and/or during the procedure of determining measurement values of the prevailing cell voltage and in particular during and in dependence upon the performed assessment procedure. By means of reducing the provided power in steps, it is possible in particular to extrapolate the values in a more exact manner or to perform a more exact comparison of the curve progressions with ideal curve progressions.

Moreover, with respect to a cost-effective as possible performance of the method in accordance with the invention, it can be expedient for the measurement periods to be as short as possible. By means of the shortest possible measurement periods, it is possible for the at least one further energy source that is provided for providing power to be configured as small as possible, for example only to provide 20 to 100 kW. It is therefore proposed in accordance with the invention that measurement values are determined within less than 10 seconds, preferably within less than 5 seconds, in particular within less than 2 seconds. By virtue of using smaller and consequently lighter energy sources, the relevant systems have a significantly reduced consumption and are consequently also advantageous from the ecological point of view. Moreover, correspondingly smaller energy sources require less installation space and as a consequence can be arranged in a considerably more flexible manner.

It is possible as a basis for assessing a state with respect to detecting a leak within the membrane of a fuel cell to provide in accordance with the invention that the procedure of assessing a state of this type includes performing at least a comparison between the measured values and the reference values, wherein the measured values preferably originate from different sensors and in particular are averaged and/or weighted prior to a being compared with the reference values. The measured values can be weighted in this case in particular with respect to the significance of the values, for example with respect to the position and/or the accuracy of corresponding sensors. Within the scope of the invention, a variably determinable value is regarded as a reference value with the aid of which it is possible to assess a state with respect to detecting a leak within the membrane of a fuel cell. In the simplest case, the reference value represents the value of the cell voltage that is to be theoretically ideally expected in the case of the corresponding provided system power. However, the reference values are in particular dependent on the system and/or dependent upon the prevailing environmental conditions, such as the ambient temperature, the ambient pressure and the like. Consequently, larger systems can for example tolerate larger leakage rates or the correspondingly used sensor system measures varying measurement values in dependence upon the environmental conditions. For this reason, it is proposed in accordance with the invention within the scope of a particularly meaningful method with respect to the provided comparison with the reference value to accordingly adjust the ideally theoretically achievable values of the cell voltage with respect to the relevant system and/or the prevailing environmental conditions.

Since, in dependence upon the comparison in accordance with the invention between measurement values and reference values, it is not always possible to explicitly assess a state with respect to a leak within a membrane of a fuel cell, it is likewise feasible in accordance with the invention to emit a warning signal in dependence upon the performed assessment procedure and/or to switch the fuel cell into an emergency operating mode. In this case, the type of the warning signal and/or the type of the emergency operating mode can be in particular dependent upon the magnitude of the leak or upon the assessment. Consequently, the fuel cell can be operated during an emergency operating mode either exclusively or at least in part by way of the at least one auxiliary energy source. In addition, such an adjustment to the operation of the fuel cell into an emergency operating mode can be performed with respect to a charge state of the at least one further energy source, or rather selectively also can be adjusted according to the prevailing concentration of pollutants in the ambient air, in particular if the air drawn in from the environment is used as the oxygen source of the relevant fuel cell system.

In order to guarantee a reliable, permanent and constantly optimized protection against leaks occurring within the membrane of the fuel cell, it is advantageously provided in accordance with the invention that the individual steps of the method are periodically repeated during the operation of the fuel cell. It is preferred that the individual steps of the method in accordance with the invention are performed in this case one after the other in short time intervals with the result that it is possible to react even to leaks of a short-term nature. Furthermore, a periodic performance of the method in accordance with the invention also renders it possible to use at least one further energy source that is smaller in size insofar as it is assumed that the energy source is recharged during the pauses by means of a recuperation procedure or the like.

The subject of the invention is likewise a system for detecting a leak within the membrane of the fuel cell. In this case, it is provided according to the subject matter of the invention that the system comprises at least one control unit for reducing the power that is provided by means of a fuel cell starting from an output power to a minimal value, at least one measuring unit for determining measurement values of the prevailing cell voltage of the fuel cell while providing the power that has reduced to the minimal value by means of the fuel cell, at least one processing unit for assessing a state of the membrane of the fuel cell with the aid of the determined measurement values for detecting a leak and also at least one further energy source for compensating in an equal amount for the power that has reduced during the procedure of determining measurement values of the prevailing cell voltage. Consequently, the system in accordance with the invention has the same advantages as have already been described in detail with regard to the method in accordance with the invention. The system in accordance with the invention can be integrated either into a mobile system or into the fuel cell system itself In order to guarantee a flexible, uncomplicated and efficient communication between the individual system units, the individual system components can communicate preferably in a wireless manner on a server basis or cloud basis and/or via the Internet. In order to realize an energy-efficient operation, the system can moreover be embodied as an adaptive learning unit and with the aid of collected data and empirical values can amend parameters and thus adjust the operation.

### BRIEF DESCRIPTION OF THE DRAWINGS

Further advantages, features and details of the invention are disclosed in the description below in which exemplary embodiments of the invention are described in detail with reference to the drawings. In this case, the features mentioned in the claims and in the description can be essential to the invention in each case individually alone or in any combination.

In the drawing:

FIG. 1a illustrates a lateral view of an intact fuel cell without a leak,

FIG. 1b illustrates a sectional view of a defective fuel cell having a leak that has occurred within the membrane of the fuel cell,

FIG. 2 illustrates the polarization curve of an intact PEM fuel cell and a defective PEM fuel cell having a leak that has occurred within the membrane,

FIG. 3 plots the progression of the cell voltage of an intact fuel cell and a defective fuel cell during the performance of the method in accordance with the invention,

FIG. 4 shows a flow diagram for illustrating the progress of the method in accordance with the invention for detecting a leak within the membrane of a fuel cell.

Identical reference numerals are used in the figures for the same technical features.

### DETAILED DESCRIPTION

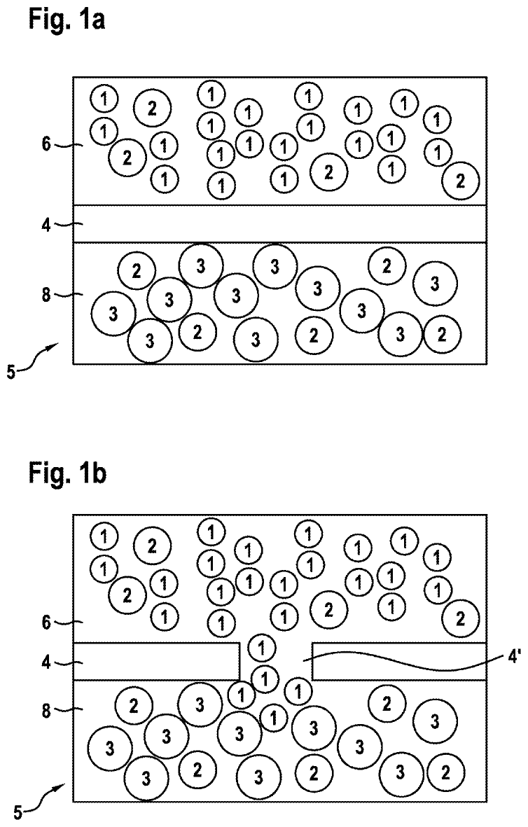

FIG. 1a illustrates a lateral view of an intact fuel cell 5 without a leak. In order to provide a greater amount of energy in a fuel cell system, a multiplicity of fuel cells 5 is combined in one fuel cell stack. For the sake of simplicity, only one fuel cell 5 is illustrated here. The fuel cell 5 comprises an anode 6 and a cathode 8 that are separated from one another by means of the membrane 4. Both the anode 6 and also the cathode 8 are electrically connected to the membrane 4. During the operation, the anode gas in the present case hydrogen 1 flows around the anode 6. In addition to hydrogen 1, the gas that is present at the anode also comprises individual nitrogen molecules 2 that can be present in the gas in particular in the case of hydrogen 1 that is recovered from the exhaust air. During the operation, the cathode gas flows around the cathode 8, in the present case the cathode gas is fresh air containing oxygen and comprising a nitrogen portion 2 and an oxygen portion 3. The membrane 4 is formed in the present case as a proton exchange membrane that is permeable for protons but as far as possible impermeable for the reactants of the fuel cell reaction, hydrogen 1 and oxygen 3. During the operation of the fuel cell 5, the fuel in this case hydrogen 1 oxidizes at the anode 6 in a catalytic manner while discharging electrons to form protons. The protons pass through the proton exchange membrane into the cathode chamber that is filled with oxygen-containing gas. The electrons are discharged from the fuel cell 5 and flow to the cathode 8 by way of an electrical connection that is not illustrated here. By means of absorbing the electrons, the oxidation agent in this case oxygen 1 is reduced at the cathode 8 to anions that react directly with the protons to form water. The described reaction creates a voltage that can be measured between the anode and the cathode and that depends in particular upon the reactants, the quality of the cell, the temperature and the cell load. The theoretically achievable cell voltage in the case of a hydrogen/oxygen fuel cell amounts to 1.23 V at a temperature of 25° C. However, generally only cell voltages of approximately 1 V are achieved owing to the reduced degrees of implementation as a result of impure reactants, wear experienced by the cells and in particular during the operation of the cells.

FIG. 1b illustrates a sectional view of a defective fuel cell 5 having a leak 4′ that has occurred within the proton exchange membrane 5. In this case, as a result of the leak, the reactants such as portions of the hydrogen 1 present in the anode chamber can penetrate the cathode chamber and react there directly with oxygen 3 to form water. The hydrogen 1 that is converted in this manner does not consequently contribute to the cell voltage with the result that in dependence upon the magnitude of the leak 4′ smaller cell voltages are measured and less energy delivered. In addition, in the case of larger leaks 4′, a direct reaction of this type can be also be problematic for reasons of safety owing to their high reaction energy.

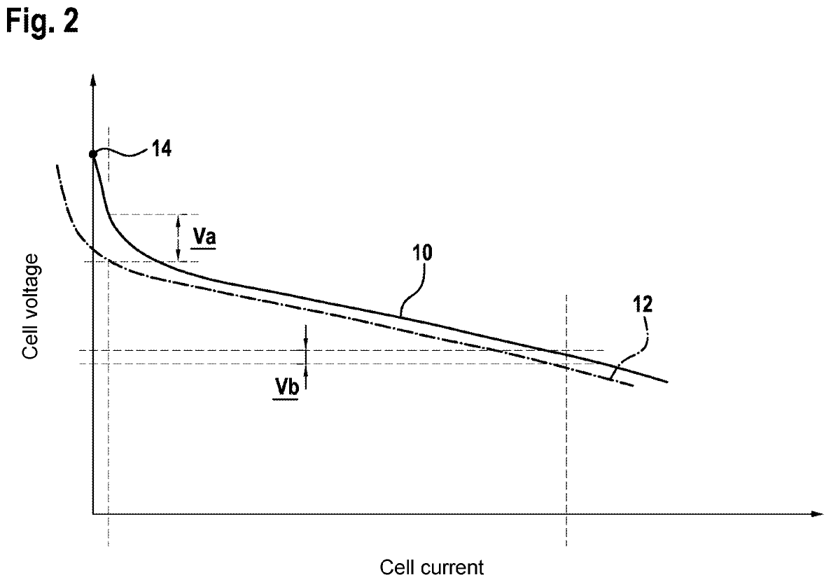

FIG. 2 illustrates the polarization curve of an intact and a defective PEM fuel cell 12 having a leak 4′ that has occurred within the membrane 4 of the cell 5. If a fuel cell 5 is loaded with a current, then the cell voltage of the loaded cell 5 drops owing to activation losses and ohmic losses as the load increases. A varying load produces in this case a characteristic continuous current-voltage progression, the so-called current-voltage curve or polarization curve of a fuel cell 5. It becomes clear with the aid of this characteristic curve progression why the method in accordance with the invention should be performed to detect a leak within a membrane 4 of a fuel cell 5 with the aid of a voltage drop owing to the measuring sensitivity at the best in the fully unloaded state of a fuel cell 5 in the case of an open circuit voltage 14 (OVC). In this state, the voltage differences Vₐ are the greatest between an intact system 10 and a defective system 12 having a leak 4′ that has occurred within the membrane 4. In contrast, if the measuring procedure is performed when the fuel cell 5 is subjected to a high load, then it is only possible with great difficulty to detect a leak 4′ with the aid of the difference of the cell voltage V_{b}.

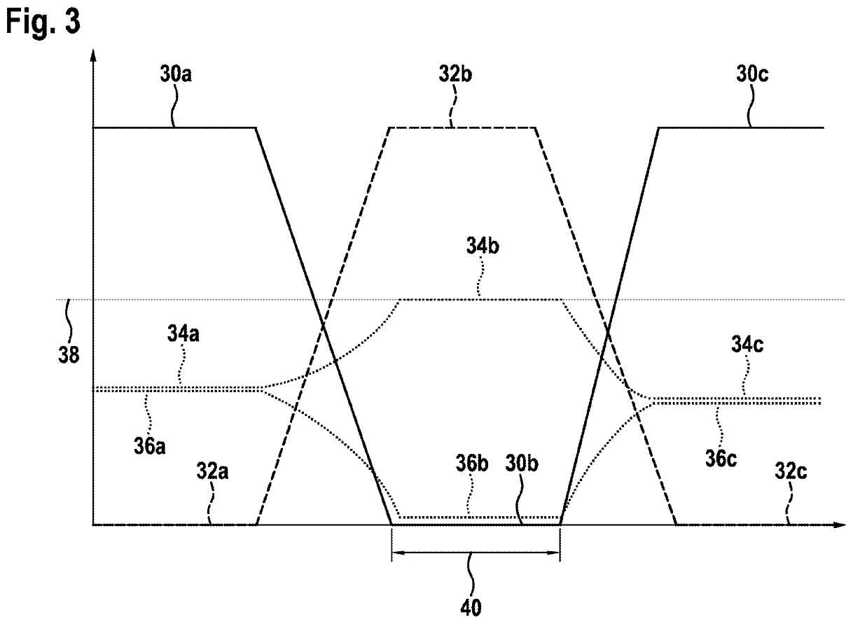

FIG. 3 illustrates the progression of the cell voltage of an intact and a defective fuel cell 5 during the performance of the method in accordance with the invention. In this case, the progression can be divided into three sections a, b, c. In this case, section a represents the progression of the cell voltage prior to a reduction of the power that is provided by the fuel cell 5 in the case of a current 30a provided by the fuel cell 5, whereas section b represents the progression of the cell voltage after a reduction of the power provided by the fuel cell 5 to a minimal value at the provided current 30b and illustrates the preferred measurement section for obtaining measurement values 40. Finally, the section c represents the progression of the cell voltage after performing the procedure of obtaining the measurement value, wherein the power provided by the fuel cell 5 is increased back to the originally provided current 30c. The curve 32 illustrates here the progression of the current provided by the at least one further energy source. The curve 34 illustrates the voltage progression of an intact fuel cell 5, whereas the curve 36 represents the voltage progression of a defective fuel cell 5 having a leak 4′ that has occurred within the membrane 4.

In a first section a during an operation of the fuel cell 5 with a current 30a provided by the cell, there can be hardly any difference between the cell voltage of the intact fuel cell 34a and the cell voltage of a defective fuel cell 36a (cf. FIG. 2 voltage difference V_{b}). However, after the reduction in accordance with the invention of the fuel cell current from the operating state 30a to a minimal value 30b, it is possible with the aid of the cell voltage to significantly differentiate between the intact system and the defective system. The cell voltage of the intact cell 34b increases to the value which the cell achieves in the unloaded state, in other words in the case of the open circuit voltage (cf. FIG. 2). In contrast, the cell voltage of the defective cell 36b drops because the leak 4′ causes an exchange between the reactants that leads to a direct reaction between hydrogen molecules 1 and oxygen molecules 3 with the result that the hydrogen 1 that is converted in this manner to form water does not amount to the cell potential. It is possible in this phase that represents the preferred measurement section and preferably lasts 2 to 5 seconds for a leak 4′ within the membrane 4 of a fuel cell 5 to be detected in a very sensitive manner.

In order to also be able to operate a fuel cell system during this phase 40, in which the power provided by the fuel cell 5 or the provided current is reduced to a minimal value 30b, the reduced power is compensated for by means of increasing the current 32a of at least one further energy source to a current 32b with the result that a constant power is made available to the relevant drive during the entire progression.

Subsequently, after measurement values have been determined for assessing a state with respect to a leak within the membrane 4 of a fuel cell 5, the current provided by the fuel cell 5 is increased back to a value 30c while the current provided by the at least one other energy source is reduced to the same extent back to a value 32c. In reaction thereto, the detected cell voltage of the intact cell drops back, whereas the cell voltage of the defective cell increases with the result that as in the first section a it is only possible with great difficulty to differentiate between the intact cell and the defects cell with the aid cell voltage.

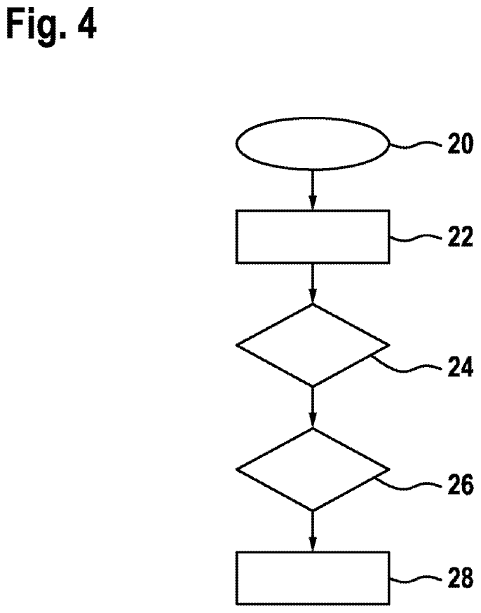

FIG. 4 shows a flow diagram for illustrating the progression of the method in accordance with the invention for detecting a leak within the membrane of a fuel cell 5. The method comprises the steps 20 to 28.

During the operation of a fuel cell system, first of all in an optional step 20 a test is performed with respect to the prevailing feasibility of the method. This optional method step is performed first and foremost in order to be able to ensure that preferably during the entire performance of the method in accordance with the invention the reduced power from the fuel cell 5 can also be compensated for by the at least one other energy source. A test of this type can in this case comprise in particular a test of the prevailing charge state of the at least one further energy source. Furthermore, the test can preferably include a comparison of the currently available charge capacity with a predicted energy consumption during the performance of the method in accordance with the invention.

After this optional step for performing the test with respect to the prevailing feasibility of the method in accordance with the invention, in step 22 the power provided by the fuel cell 5 is reduced starting from an output power to a minimal value and this power is simultaneously compensated by means of at least one other energy source. The minimal value of the power provided by the fuel cell 5 is in the ideal case a value of 0 Watt, in other words the value that can be measured if the fuel cell 5 is not providing any power. However, it is likewise possible that the minimal value is higher, for example multiple kilowatt or the like. A reduction of the power to the minimal value can occur in this case in steps or also continuously. The at least one further energy source is preferably an electrical, in particular electrochemical, energy source.

After the reduction of the power provided by the fuel cell 5 to the minimal value and the simultaneous compensation by means of at least one further energy source, measurement values of the prevailing cell voltage of the fuel cell 5 are determined in step 24 of the method in accordance with the invention. In this case, it is possible to select preferably freely and in a variable manner both the time interval for determining the measurement values and also the rate at which the measurement values are determined. The measurement values are preferably determined in this case in a small time frame, for example within 2 to 5 seconds.

After the measurement values of the prevailing cell voltage of the fuel cell 5 have been determined, a state of the membrane of the fuel cell 5 is finally assessed within the scope of the method in accordance with the invention in step 26 with the aid of the determined measurement values for detecting a leak. In this case, the procedure of assessing a state of this type currently includes performing at least one comparison between the measured values and reference values, wherein the measured values preferably originate from different sensors and are in particular averaged and/or weighted prior to being compared with reference values. The reference value is in this case currently preferably a variably determinable value, with the aid of which it is possible to assess a state with respect to detecting a leak 4′ within the membrane 4 of a fuel cell 5. In the simplest case, the reference value represents the value of the cell voltage that is theoretically ideally to be expected in the case of the correspondingly provided current. However, the reference values are in particular dependent upon the system and/or dependent upon the prevailing environmental conditions, with the result that the reference values should preferably be accordingly adjusted prior to a meaningful comparison.

Finally, after the assessment procedure has been performed, in a subsequent step 28 at least insofar as a leak 4′ has not been detected the power provided by the fuel cell 5 is increased while correspondingly reducing the power provided by the at least one other energy source. In the event that a leak 4′ has been detected within the membrane 4 of the relevant fuel cell 5 within the scope of the assessment procedure, then warning signals can be generated alternatively or cumulatively and/or the fuel cell 5 can be switched into an emergency operating mode or not be switched back on.

1. A method for detecting a leak (4′) within a membrane (4) of a fuel cell (5) during the operation of a motor vehicle, the method comprising the steps of:
a) reducing the power that is provided by means of the fuel cell (5) starting from an output power to a minimal value;
b) determining measurement values of the prevailing cell voltage of the fuel cell (5) while providing the power that has reduced to the minimal value by means of the fuel cell (5);
c) assessing the state of the membrane (4) of the fuel cell (5) with the aid of the determined measurement values for detecting a leak (4);
wherein the reduced power from the fuel cell (5) during the procedure of determining the measurement values of the prevailing cell voltage is compensated for in an equal amount by means of at least one further energy source.

2. The method as claimed in claim 1, wherein prior to the reduction of the provided power a test is performed with respect to the prevailing feasibility of the method, wherein the test includes performing a comparison of the duration of the operation of the fuel cell (5) under full load with a comparison value.

3. The method as claimed in claim 1, wherein the power that is provided by means of the fuel cell (5) reduces during the method—and is increased back to the same extent after the measurement values of the prevailing cell voltage have been determined, after and in dependence upon the performed assessment procedure, wherein the reduced power from the fuel cell (5) is compensated for by means of the at least one further energy source and this power that is provided by means of the at least one further energy source is reduced accordingly by the same amount after the power that is provided by the fuel cell (5) increases.

4. The method as claimed in claim 1, wherein the power provided by means of the fuel cell (5) is reduced prior to and/or during the procedure of determining measurement values of the prevailing cell voltage and in dependence upon the performed assessment procedure to a value of less than 2% of the maximal power.

5. The method as claimed in claim 1, wherein the power that is provided by means of the fuel cell (5) is reduced in steps prior to and/or during the procedure of determining measurement values of the prevailing cell voltage.

6. The method as claimed in claim 1, wherein the procedure of determining measurement values is performed within less than 10 seconds.

7. The method as claimed in claim 1, wherein the procedure of assessing a state for detecting a leak (4′) within the membrane (4) of a fuel cell (5) includes performing at least one comparison between the measured values and reference values, wherein the measured values originate from different sensors.

8. The method as claimed in claim 1, wherein in dependence upon the assessment a warning signal is emitted and/or the fuel cell (5) is switched into an emergency operating mode.

9. The method as claimed in claim 1, wherein the individual steps of the method are repeated periodically during the operation of the fuel cell (5).

10. The method as claimed in claim 1, wherein the method is used in a vehicle, in particular in a fuel cell vehicle.

11. A system for operating a motor vehicle, the system comprising:
at least one control unit for reducing the power that is provided by means of a fuel cell (5) starting from an output power to a minimal value,
at least one measuring unit for determining measurement values of the prevailing cell voltage of the fuel cell (5) while providing the reduced power to the minimal value by means of the fuel cell (5),
at least one processing unit for assessing a state of the membrane (4) of the fuel cell (5) with the aid of the determined measurement values for detecting a leak (4′);
wherein the system comprises at least one further energy source for compensating in an equal amount for the power that has reduced during the procedure of determining measurement values of the prevailing cell voltage.
